(19) United States
(12) Patent Application Publication
(10) Pub. No.: US 2021/0376161 A1
(43) Pub. Date: Dec. 2, 2021

(54) INVERTER EMPOLYING THIN-FILM TRASISTOR FABRICATED BY ADJUSTING SILICON CONTENT AND METHOD FOR MANUFACTURING SAME

(71) Applicant: CHEONGJU UNIVERSITY INDUSTRY & ACADEMY COOPERATION FOUNDATION, Cheongju-si, Chungcheongbuk-do (KR)

(72) Inventor: Sang Yeol LEE, Seoul (KR)

(21) Appl. No.: 17/277,998

(22) PCT Filed: Sep. 19, 2019
(86) PCT No.: PCT/KR2019/012160

§ 371 Date: Mar. 19, 2021

(30) Foreign Application Priority Data
Sep. 19, 2018 (KR) 10-2018-0112371

(51) Int. Cl. H01L 29/786; H01L 27/088; H01L 21/8236; H02M 7/537

(52) U.S. Cl. CPC H01L 29/78693; H02M 7/537; H01L 21/8236; H01L 27/0883

(57) ABSTRACT

The present invention relates to an inverter employing a thin film transistor fabricated by adjusting a silicon content and a method for manufacturing the same, and the inverter employing a thin film transistor fabricated by adjusting a silicon content includes a depletion mode transistor including a first gate electrode formed on a substrate, a first insulating layer formed on the first gate electrode, and a first source electrode, a first drain electrode, and a first channel layer formed on the first insulating layer, an enhancement mode transistor including a second gate electrode formed on the substrate, a second insulating layer formed on the second gate electrode, and a second source electrode, a second drain electrode, and a second channel layer formed on the second insulating layer; and a wiring unit electrically connecting the electrodes, and the first channel layer and the second channel layer are formed of amorphous silicon oxide layers having different silicon contents. According to the present invention, an inverter may be configured by adjusting a silicon content of a channel layer with the same electrode layer, only using an oxide thin film transistor of an n channel layer in a CMOS including both a p channel layer and an n channel layer to cause a difference in a threshold voltage.

### TECHNICAL FIELD

The present invention relates to an inverter employing a thin film transistor fabricated by adjusting silicon contents of an enhancement mode transistor and a depletion mode transistor and a method for manufacturing the same.

### BACKGROUND ART

An operation mode of the transistor is classified into a depletion mode and an enhancement mode. In a depletion mode transistor, even though a gate voltage is not applied, a channel is open so that a current flows and in an enhancement mode transistor, when a gate voltage is not applied, a channel is closed so that the current does not flow. In a logic circuit which is configured only by a depletion mode transistor, a leakage current is large and a proper operation of a logic circuit is difficult so that there is a limitation in implementing a logic circuit. For example, according to a normal operation of an inverter logic circuit, when an input voltage is logical “0”, an output voltage needs to be logical “1”. If not, a level shifting element which is an additional device needs to be mounted to adjust an operating voltage.

In this case, the additional device causes the complexity of the circuit and the increased power consumption. Further, an inverter circuit configured only by an enhancement mode transistor has a low inverter gain and a poor swing characteristic so that there is a limitation in implementing a high performance logic circuit. Accordingly, a method of implementing a high performance logic circuit using both the depletion mode transistor and the enhancement mode transistor is necessary.

Generally, a silicon (Si) based inverter is a complementary metal oxide semiconductor (CMOS) inverter which includes both an n-channel metal oxide semiconductor (NMOS) transistor and a p-channel metal oxide semiconductor (PMOS) transistor. When a Si layer is used as a channel layer, an NMOS or a PMOS transistor may be easily manufactured by varying types of elements to be doped on the channel layer.

However, when a channel layer is formed by an oxide semiconductor, it is difficult to implement a p channel layer due to a material characteristic of the oxide semiconductor so that it is difficult to implement an inverter including both the n-channel transistor and the p-channel transistor.

### DISCLOSURE

### Technical Problem

An object of the present invention is to provide an inverter employing a thin film transistor fabricated by adjusting a silicon content which configures an inverter using a difference in threshold voltages by adjusting a silicon content of a channel layer of a depletion mode transistor and a silicon content of a channel layer of an enhancement mode transistor to be different from each other.

### Technical Solution

In order to achieve the above-mentioned object, an inverter employing a thin film transistor fabricated by adjusting a silicon content according to an exemplary embodiment of the present invention includes a depletion mode transistor including a first gate electrode formed on a substrate, a first insulating layer formed on the first gate electrode, and a first source electrode, a first drain electrode, and a first channel layer formed on the first insulating layer, an enhancement mode transistor including a second gate electrode formed on the substrate, a second insulating layer formed on the second gate electrode, and a second source electrode, a second drain electrode, and a second channel layer formed on the second insulating layer; and a wiring unit electrically connecting the electrodes, and the first channel layer and the second channel layer are formed of amorphous silicon oxide layers having different silicon contents.

Here, the amorphous silicon oxide layer may be formed by at least one of an amorphous silicon zinc tin oxide layer SZTO and an amorphous silicon indium zinc oxide layer SIZO and a silicon content of the second channel layer may be larger than a silicon content of the first channel layer.

Further, the amorphous silicon zinc tin oxide layer SZTO or the amorphous silicon indium zinc oxide layer SIZO may further include at least one element of aluminum (Al), gallium (Ga), hafnium (Hf), zirconium (Zr), lithium (Li), potassium (K), Titanium (Ti), germanium (Ge), and niobium (Nb).

Further, the second channel layer and the first channel layer may be formed such that a difference in the silicon contents is 0.5 weight percent (wt. %) or more.

Further, a silicon content of the first channel layer is adjusted between 0.001 and 20 weight percent (wt. %) and a silicon content of the second channel layer is adjusted between 0.01 and 30 weight percent (wt. %).

Further, the wiring unit connects the second gate electrode to an input terminal, connects the first source electrode, the first gate electrode, and the second drain electrode to an output terminal, connects the first drain electrode to an internal power source, and connects the second source electrode to a ground terminal.

Further, electrodes may be formed by at least one of aluminum (Al), titanium (Ti), ITO, ISO, copper (Cu), and gold (Au) or a combination thereof with a thickness of 10 nanometers (nm) to 40 nanometers (nm) by an ion beam deposition or thermal deposition method.

The wiring unit may be formed of at least one of conductive materials including aluminum (Al), gold (Au), platinum (Pt), or copper (Cu) or a combination thereof.

According to another aspect of the present invention, a manufacturing method of an inverter employing a thin film transistor fabricated by adjusting a silicon content includes forming first and second electrodes on a substrate; forming first and second insulating layers above the first and second gate electrodes, respectively; forming first and second channel layers on the first and second insulating layers, respectively; forming electrode layers on the first and second channel layers; forming a first source electrode, a first drain electrode, a second source electrode, and a second drain electrode by partially removing the electrode layers by a photo exposure process or a lift-off process after forming the electrode layers; and electrically connecting the electrodes.

Further, in the forming of first and second channel layers, the second channel layer and the first channel layer are formed by amorphous silicon oxide layers and a silicon content of the second channel layer is larger than that of the first channel layer.

Here, the difference in the silicon contents is 0.5 weight percent (wt. %) or more.

Further, a silicon content of the first channel layer is adjusted between 0.001 and 20 weight percent (wt. %) and a silicon content of the second channel layer is adjusted between 0.01 and 30 weight percent (wt. %).

### Advantageous Effects

According to the present invention, an inverter may be configured by causing a difference in a threshold voltage by adjusting a silicon content of a channel layer with the same electrode layer, only using an oxide thin film transistor of an n channel layer, in a CMOS including both a p channel layer and an n channel layer.

### DESCRIPTION OF DRAWINGS

FIG. 1 is a cross-sectional view of an inverter employing a thin film transistor fabricated by adjusting a silicon content according to an exemplary embodiment of the present invention.

FIG. 2 is a circuit diagram of an inverter employing a thin film transistor fabricated by adjusting a silicon content according to an exemplary embodiment of the present invention.

FIG. 3 is a view for explaining a voltage-current characteristic in accordance with a silicon content of a thin film transistor fabricated by adjusting a silicon content according to an exemplary embodiment of the present invention.

FIG. 4 is a view for explaining a resistance characteristic in accordance with a silicon content of a thin film transistor fabricated by adjusting a silicon content according to an exemplary embodiment of the present invention.

FIG. 5 is a view for explaining a band bending characteristic in accordance with a silicon content of a thin film transistor fabricated by adjusting a silicon content according to an exemplary embodiment of the present invention.

FIG. 6 is a view for explaining a voltage transfer characteristic and a voltage gain of a thin film transistor fabricated by adjusting a silicon content according to an exemplary embodiment of the present invention.

### BEST MODE

Those skilled in the art may make various modifications to the present disclosure and the present disclosure may have various embodiments thereof, and thus specific embodiments will be described in detail with reference to the drawings. However, this does not limit the present disclosure within specific exemplary embodiments, and it should be understood that the present disclosure covers all the modifications, equivalents and replacements within the spirit and technical scope of the present disclosure. In the description of respective drawings, similar reference numerals designate similar elements.

Terms such as first, second, A, or B may be used to describe various components but the components are not limited by the above terms. The above terms are used only to discriminate one component from the other component. For example, without departing from the scope of the present disclosure, a first component may be referred to as a second component, and similarly, a second component may be referred to as a first component. A term of and/or includes combination of a plurality of related elements or any one of the plurality of related elements.

It should be understood that, when it is described that an element is “coupled” or “connected” to another element, the element may be directly coupled or directly connected to the other element or coupled or connected to the other element through a third element. In contrast, when it is described that an element is “directly coupled” or “directly connected” to another element, it should be understood that no element is not present therebetween.

Terms used in the present application are used only to describe a specific exemplary embodiment, but are not intended to limit the present invention. A singular form may include a plural form if there is no clearly opposite meaning in the context. In the present application, it should be understood that term “include” or “have” indicates that a feature, a number, a step, an operation, a component, a part or the combination thoseof described in the specification is present, but do not exclude a possibility of presence or addition of one or more other features, numbers, steps, operations, components, parts or combinations, in advance.

If it is not contrarily defined, all terms used herein including technological or scientific terms have the same meaning as those generally understood by a person with ordinary skill in the art. Terms defined in generally used dictionary shall be construed that they have meanings matching those in the context of a related art, and shall not be construed in ideal or excessively formal meanings unless they are clearly defined in the present application.

In the specification and the claim, unless explicitly described to the contrary, the word “comprise” and variations such as “comprises” or “comprising”, will be understood to imply the inclusion of status elements but not the exclusion of any other elements.

Hereinafter, exemplary embodiments according to the present invention will be described in detail with reference to accompanying drawings.

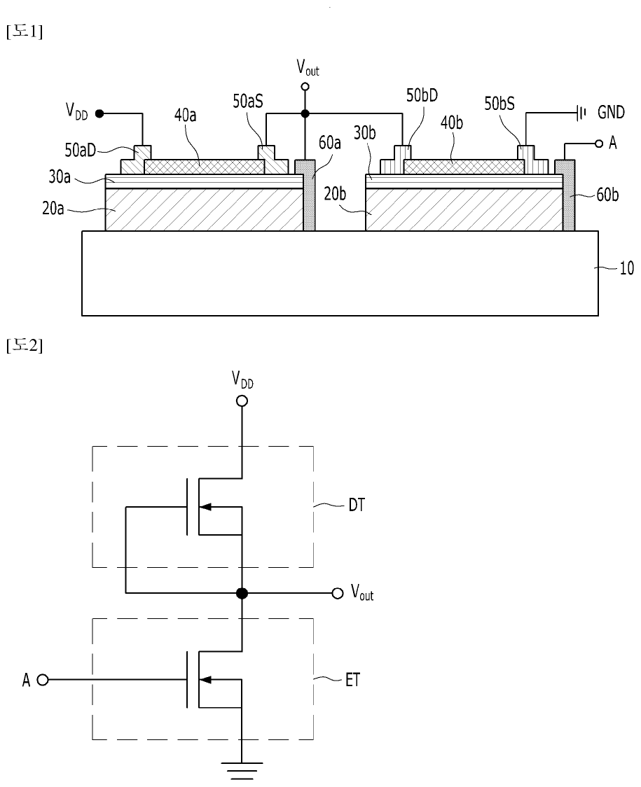

FIG. 1 is a cross-sectional view of an inverter employing a thin film transistor fabricated by adjusting a silicon content according to an exemplary embodiment of the present invention.

Referring to FIG. 1, an inverter employing a thin film transistor fabricated by adjusting a silicon content according to an exemplary embodiment of the present invention includes a depletion mode transistor, an enhancement mode transistor, and a wiring unit.

The depletion mode transistor includes a first channel layer 40a formed on a substrate 10 and a first source electrode 50aS and a first drain electrode 50aD formed on the first channel layer 40a. The depletion mode transistor may further include a first gate electrode 20a and a first insulating layer 30a between the substrate 10 and the first channel layer 40a.

The enhancement mode transistor includes a second channel layer 40b formed on the substrate 10 and a second source electrode 50bS and a second drain electrode 50bD formed on the second channel layer 40b. The enhancement mode transistor may further include a second gate electrode 20b and a second gate insulating layer 30b between the substrate 10 and the second channel layer 40b. The source/drain electrodes may be formed by forming on the entire surfaces of the first and second channel layers and then partially removing by a photo-exposure process or a lift-off process.

The first and second channel layers 40a and 40b may be formed of an amorphous silicon oxide layer. Here, the amorphous silicon oxide layer may be formed by at least one of an amorphous silicon zinc tin oxide layer SZTO and an amorphous silicon indium zinc oxide layer SIZO and a silicon content of the second channel layer may be larger than a silicon content of the first channel layer. As described above, the difference in the threshold voltage is caused by the different silicon contents of the first and second channel layers to adjust to be operated as an inverter. The amorphous silicon zinc tin oxide layer SZTO or the amorphous silicon indium zinc oxide layer SIZO may further include at least one element of aluminum (Al), gallium (Ga), hafnium (Hf), zirconium (Zr), lithium (Li), potassium (K), titanium (Ti), germanium (Ge), and niobium (Nb). The second channel layer and the first channel layer may be formed such that a difference in the silicon contents is 0.5 weight percent (wt. %) or more. Further, a silicon content of the first channel layer is adjusted between 0.001 and 20 weight percent (wt. %) and a silicon content of the second channel layer is adjusted between 0.01 and 30 weight percent (wt. %).

The first drain electrode 50aD and the first source electrode 50aS which configure the depletion mode transistor are formed of a first electrode material and the second drain electrode 50bD and the second source electrode 50bS which configure the enhancement mode transistor are formed of a second electrode material. In this case, the second electrode material refers to a material having a threshold voltage which is relatively higher than that of the first electrode material. Specifically, the first electrode material may be formed of at least one element of gold (Au), silver (Ag), copper (Cu), aluminum (Al), titanium (Ti), tungsten (W), and molybdenum (Mo) and the second electrode material may be formed of indium tin oxide (In—SnO). Alternatively, the first electrode material may be formed of at least one element of gold (Au), silver (Ag), copper (Cu), aluminum (Al), titanium (Ti), tungsten (W), and molybdenum (Mo) and the second electrode material may be formed of indium silicon oxide (In—SiO). In addition, electrodes may be formed of at least one of aluminum (Al), titanium (Ti), ITO, ISO, copper (Cu), and gold (Au) or a combination thereof with a thickness of 10 nanometers (nm) to 40 nanometers (nm) by an ion beam deposition or thermal deposition method.

The wiring unit electrically connects the first and second gate electrodes 20a and 20b, the first and second drain electrodes 50aD and 50bD, and the first and second source electrodes 50aS and 50bS. The wiring unit connects the first source electrode 50aS, the first gate electrode 20a, and the second drain electrode 50bD to an output terminal Vout and connects the second gate electrode 20b to an input terminal to form an inverter logic circuit. At this time, the first drain electrode 50aD may be connected to an internal power source VDD and the first source electrode 50aS and the second source electrode 50bS may be connected to the ground.

The wiring unit may be formed of at least one of conductive materials including aluminum (Al), gold (Au), platinum (Pt), or copper (Cu) or a combination thereof.

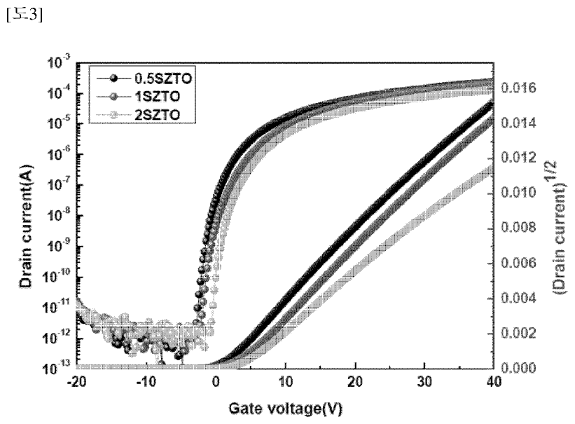

FIG. 2 is a circuit diagram of an inverter employing a thin film transistor fabricated by adjusting a silicon content according to an exemplary embodiment of the present invention.

Referring to FIG. 2, in a circuit diagram of an inverter employing a thin film transistor fabricated by adjusting a silicon content according to an exemplary embodiment of the present invention, the drain electrode of the depletion mode transistor DT is connected to the internal power source VDD and the source electrode of the depletion mode transistor DT is connected to the drain electrode of the enhancement mode transistor ET, according to the connection pattern of the wiring unit described above.

Further, the gate electrode of the depletion mode transistor DT may be connected to the output terminal Vout together with the source electrode of the depletion mode transistor DT and the drain electrode of the enhancement mode transistor ET. The gate electrode of the enhancement mode transistor ET is connected to an input terminal A and the source electrode of the enhancement mode transistor ET is connected to the ground.

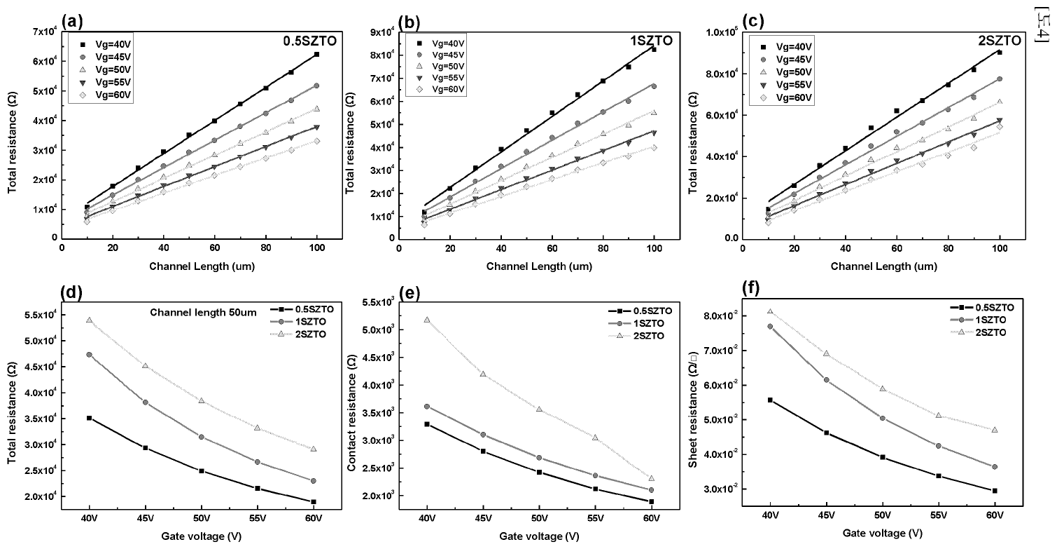

FIG. 3 is a view for explaining a voltage-current characteristic in accordance with a silicon content of a thin film transistor fabricated by adjusting a silicon content according to an exemplary embodiment of the present invention.

Referring to FIG. 3, it is confirmed that in the thin film transistor fabricated by adjusting the silicon content according to the exemplary embodiment of the present invention, as the silicon content changes, a drain current with respect to the gate voltage changes.

Specifically, it is confirmed that as the silicon content is increased to 0.5 wt. % (0.5 SZTO), 1 wt. % (1 SZTO), and 2 wt. % (2 SZTO), the threshold voltage Vth moves to a positive direction. Another characteristics such as on-current Ion, on/off current Ion/off, and field effect mobility μFE are reduced as the silicon content increases. Characteristic values in accordance with silicon contents are represented in Table 1.

TABLE 1

| | Vₜₕ | Iₒₙ | I_{off} | I_{on/off} | μ_{FE} | S.S |
|---|---|---|---|---|---|---|
| 0.5SZTO | 1.08 | 2.3.E−04 | 1.1.E−13 | 2.1.E+09 | 22.610 | 0.46 |
| 1SZT0 | 3.28 | 2.1.E−04 | 3.8.E−13 | 5.4.E+08 | 21.815 | 0.44 |
| 2SZTO | 3.84 | 1.3.E−04 | 3.2.E−13 | 4.1.E+08 | 14.373 | 0.47 |

When the silicon content of the channel layer of the depletion mode transistor and the silicon content of the channel layer of the enhancement mode transistor are 0.5 wt. % or more, as represented in the above table, the difference in the threshold voltage Vth is 1 V or more so that it normally operates as an inverter. However, when the silicon content of the channel layer of the depletion mode transistor and the silicon content of the channel layer of the enhancement mode transistor are 0.5 wt. % or less, the difference in the threshold voltage changes in an error range so that it may normally operate as an inverter or it may not normally operate as an inverter. Accordingly, it is confirmed that only when the silicon content of the channel layer of the enhancement mode transistor is 0.5 wt. % or more than the silicon content of the channel layer of the enhancement mode transistor, it normally operates as an inverter.

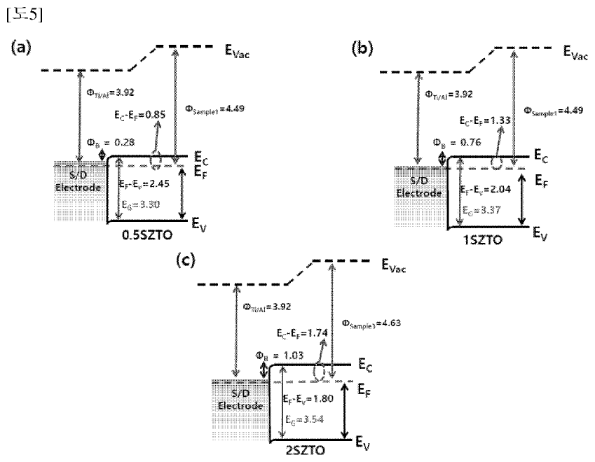

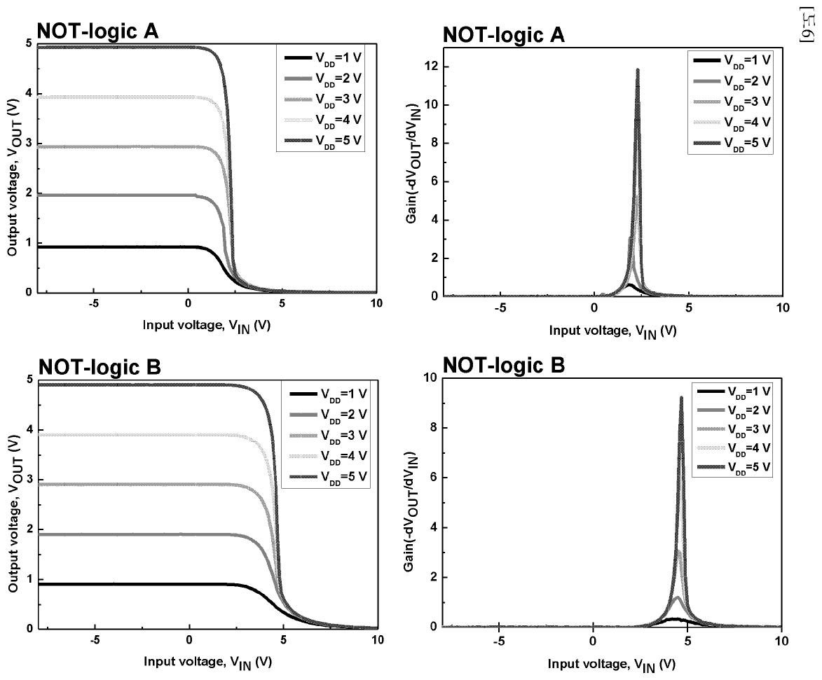

FIG. 4 is a view for explaining a resistance characteristic in accordance with a silicon content of a thin film transistor fabricated by adjusting a silicon content according to an exemplary embodiment of the present invention and FIG. 5 is a view for explaining a band bending characteristic in accordance with a silicon content of a thin film transistor fabricated by adjusting a silicon content according to an exemplary embodiment of the present invention.

Referring to FIG. 4, a resistance characteristic of the thin film transistor fabricated by adjusting a silicon content according to the exemplary embodiment of the present invention changes in accordance with the silicon content. A contact resistance Rc and a sheet resistance Rsh are illustrated in FIG. 4(a) to FIG. 4(c) and extracted by the following Equations 1 and 2.

$$\begin{matrix}{R}_{t} = 2 {R}_{c} + {R}_{sh} \frac{L}{W} & [ Equation 1 ] \\ {R}_{sh} = {slope}^{*} W & [ Equation 2 ]\end{matrix}$$

The contact resistance Rc indicates a contact resistance between the channel layer and the source/drain electrodes and the sheet resistance Rsh indicates a sheet resistance of the channel layer. “Slope” indicates a slope of a fitting-line at the total resistance Rt.

As a result, it is confirmed that as the silicon content increases, Rc, Rsh, and Rt increase.

Referring to FIG. 5, the band bending characteristic according to the silicon content of the thin film transistor fabricated by adjusting the silicon content according to the exemplary embodiment of the present disclosure is an energy bending phenomenon between the source/drain electrodes and the channel layer and it is confirmed that the silicon content increases, the magnitude of Ec increases.

FIG. 6 is a view for explaining a voltage transfer characteristic and a voltage gain of a thin film transistor fabricated by adjusting a silicon content according to an exemplary embodiment of the present invention.

Referring to FIG. 6, in the thin film transistor fabricated by adjusting the silicon content according to the exemplary embodiment of the present disclosure, as the VDD increases, an inverting characteristic of an output voltage VOUT with respect to the input voltage VIN is clear. Further, it is confirmed that the output gain with respect to the input voltage also increases.

According to the present invention, it is confirmed that an inverter is configured by causing a difference in a threshold voltage by adjusting a silicon content of a channel layer with the same electrode layer, only using an oxide thin film transistor of an n channel layer in a CMOS including both a p channel layer and an n channel layer and when the silicon content is 0.5 wt. % or more, the inverting characteristic is excellent.

It will be appreciated that various exemplary embodiments of the present disclosure have been described herein for purposes of illustration, and that various modifications, changes, and substitutions may be made by those skilled in the art without departing from the scope and spirit of the present disclosure. Therefore, the exemplary embodiments of the present disclosure are provided for illustrative purposes only but not intended to limit the technical concept of the present disclosure. The scope of the technical concept of the present disclosure is not limited thereto. The protective scope of the present disclosure should be construed based on the following claims, and all the technical concepts in the equivalent scope thereof should be construed as falling within the scope of the present disclosure.

1. An inverter employing a thin film transistor fabricated by adjusting a silicon content, comprising:
a depletion mode transistor including a first gate electrode formed on a substrate, a first insulating layer formed on the first gate electrode, and a first source electrode, a first drain electrode, and a first channel layer formed on the first insulating layer;
an enhancement mode transistor including a second gate electrode formed on the substrate, a second insulating layer formed on the second gate electrode, and a second source electrode, a second drain electrode, and a second channel layer formed on the second insulating layer; and
a wiring unit electrically connecting the electrodes,
wherein the first channel layer and the second channel layer are formed of amorphous silicon oxide layers having different silicon contents.

2. The inverter of claim 1, wherein the amorphous silicon oxide layer is formed by at least one of an amorphous silicon zinc tin oxide layer SZTO and an amorphous silicon indium zinc oxide layer SIZO and a silicon content of the second channel layer is larger than a silicon content of the first channel layer.

3. The inverter of claim 2, wherein the amorphous silicon zinc tin oxide layer SZTO or the amorphous silicon indium zinc oxide layer SIZO further includes at least one element of aluminum (Al), gallium (Ga), hafnium (Hf), zirconium (Zr), lithium (Li), potassium (K), Titanium (Ti), germanium (Ge), and niobium (Nb).

4. The inverter of claim 2, wherein the second channel layer and the first channel layer are formed such that a difference in the silicon contents is 0.5 weight percent (wt. %) or more.

5. The inverter of claim 4, wherein a silicon content of the first channel layer is adjusted between 0.001 and 20 weight percent (wt. %) and a silicon content of the second channel layer is adjusted between 0.01 and 30 weight percent (wt. %).

6. The inverter of claim 1, wherein the wiring unit connects the second gate electrode to an input terminal, connects the first source electrode, the first gate electrode, and the second drain electrode to an output terminal, connects the first drain electrode to an internal power source, and connects the second source electrode to a ground terminal.

7. The inverter of claim 1, wherein the electrodes are formed by at least one of aluminum (Al), titanium (Ti), ITO, ISO, copper (Cu), and gold (Au) or a combination thereof with a thickness of 10 nanometers (nm) to 40 nanometers (nm) by an ion beam deposition or thermal deposition method.

8. The inverter of claim 1, wherein the wiring unit is formed of at least one of conductive materials including aluminum (Al), gold (Au), platinum (Pt), or copper (Cu) or a combination thereof.

9. A manufacturing method of an inverter employing a thin film transistor fabricated by adjusting a silicon content, the manufacturing method comprising:
forming first and second electrodes on a substrate;
forming first and second insulating layers above the first and second gate electrodes, respectively;
forming first and second channel layers on the first and second insulating layers, respectively;
forming electrode layers on the first and second channel layers;
forming a first source electrode, a first drain electrode, a second source electrode, and a second drain electrode by partially removing the electrode layers by a photo exposure process or a lift-off process after forming the electrode layers; and
electrically connecting the electrodes.

10. The manufacturing method of claim 9, wherein in the forming of first and second channel layers, the second channel layer and the first channel layer are formed by amorphous silicon oxide layers and a silicon content of the second channel layer is larger than that of the first channel layer.

11. The manufacturing method of claim 10, wherein the difference in the silicon contents is 0.5 weight percent (wt. %) or more.

12. The manufacturing method of claim 11, wherein a silicon content of the first channel layer is adjusted between 0.001 and 20 weight percent (wt. %) and a silicon content of the second channel layer is adjusted between 0.01 and 30 weight percent (wt. %).
